(19) United States
(12) Patent Application Publication
(10) Pub. No.: US 2023/0089160 A1
(43) Pub. Date: Mar. 23, 2023

(54) TOUCH-TO-DISPLAY NOISE MITIGATION FOR TOUCHSCREEN DEVICES

(71) Applicant: Synaptics Incorporated, San Jose, CA (US)

(72) Inventors: Jonathan L. Losh, San Jose, CA (US); Daisuke Ito, Tokyo (JP)

(21) Appl. No.: 17/481,573

(22) Filed: Sep. 22, 2021

(51) Int. Cl. G06F 3/041; G06F 3/044; H03K 17/96

(52) U.S. Cl. CPC G06F 3/04166; G06F 3/044; H03K 17/962

(57) ABSTRACT

A touchscreen display device include a display device and a touch sensor. The display device is configured to output image data during a display operation of the touchscreen display device. The touch sensor configured to perform touch sensing using a step-and-wait sensing scheme, wherein performing touch sensing includes: generating a driving waveform during the display operation of the touchscreen display device, wherein the driving waveform is a quadrature trapezoidal waveform, a triangular waveform, or a harmonic reject waveform; obtaining resulting signals based on the generated driving waveform; and determining presence and/or movement of an input object in a sensing region of the touchscreen display device based on the obtained resulting signals.

### TECHNICAL FIELD

The described embodiments relate generally to electronic devices, and more specifically, to capacitive sensors.

### BACKGROUND

Input devices, including capacitive sensor devices (e.g., touchpads or touch sensor devices), are widely used in a variety of electronic systems. A capacitive sensor device may include a sensing region, often demarked by a surface, in which the capacitive sensor device determines the presence, location and/or motion of one or more input objects. Capacitive sensor devices may be used to provide interfaces for the electronic system. For example, capacitive sensor devices may be used as input devices for larger computing systems (e.g., opaque touchpads integrated in, or peripheral to, notebook or desktop computers). Capacitive sensor devices are also often used in smaller computing systems (e.g., touchscreens integrated in cellular phones). Capacitive sensor devices may also be used to detect input objects (e.g., finger, styli, pens, fingerprints, etc.).

For touchscreen devices which include capacitive sensors integrated with displays, display-to-touch noise is often a concern, as the display signal may interfere with resulting signals detected via receiver electrodes of the capacitive sensor, and there are many approaches for dealing with display-to-touch noise. However, as touchscreen technology progresses and touchscreen devices are becoming thinner and thinner (e.g., such as the case of Y-OCTA (Youm On-Cell Touch AMOLED) displays in which the touch sensor components are very close to the display components—e.g., closer than in conventional touchscreens by up to a factor of ten), touch-to-display noise may also become a problem, as emissions from the touch sensor electrodes may interfere with display signals output on display pixels to create artifacts in the displayed image.

A number of approaches to address touch-to-display noise have been attempted, but none have produced satisfactory results. For example, one method is to synchronize touch sensing pulses to display update rates, but this locks the touch frequency to the HLine frequency, thereby creating additional problems such as problems relating to charger noise. In another example, a square wave touch sensing frequency is moved sufficiently far away from the HLine frequency, but this causes problems with the touch sensor response to input objects.

### SUMMARY

In an exemplary embodiment, the disclosure provides a touchscreen display device. The touchscreen display device includes a display device and a touch sensor. The display device is configured to output image data during a display operation of the touchscreen display device. The touch sensor is configured to perform touch sensing using a step-and-wait sensing scheme. Performing touch sensing includes: generating a driving waveform during the display operation of the touchscreen display device, wherein the driving waveform is a quadrature trapezoidal waveform, a triangular waveform, or a harmonic reject waveform; obtaining resulting signals based on the generated driving waveform; and determining presence and/or movement of an input object in a sensing region of the touchscreen display device based on the obtained resulting signals.

The display device and the touch sensor may be disposed in respective layers of a stackup, wherein the distance between the display device and the touch sensor is less than 20 μm.

In the case of the driving waveform being the harmonic reject waveform, the touch sensor comprises a harmonic rejection mixer configured to generate the harmonic reject waveform, and wherein the harmonic rejection mixer comprises a plurality of square wave generators, each configured to generate a square wave having a respective amplitude and phase offset. Additionally, the harmonic reject waveform may be configured such that the harmonics of the harmonic reject waveform do not include third and fifth harmonics of a square wave.

In another exemplary embodiment, the disclosure provides a method for step-and-wait sensing. The method includes: generating, by a touch sensor of a touchscreen display device, a driving waveform during a display operation of a display device of the touchscreen display device, wherein the driving waveform is a quadrature trapezoidal waveform, a triangular waveform, or a harmonic reject waveform; obtaining, by the touch sensor, resulting signals based on the generated driving waveform; and determining, by the touch sensor, presence and/or movement of an input object in a sensing region of the touchscreen display device based on the obtained resulting signals.

In yet another exemplary embodiment, the disclosure provides a display stackup. The display stackup includes: a display layer comprising a plurality of display pixels configured to output image data during a display operation; and a touch sensor layer, wherein a touch sensor of the touch sensor layer is configured to perform touch sensing using a step-and-wait sensing scheme. Performing touch sensing includes: generating a driving waveform during the display operation, wherein the driving waveform is a quadrature trapezoidal waveform, a triangular waveform, or a harmonic reject waveform; obtaining resulting signals based on the generated driving waveform; and determining presence and/or movement of an input object in a sensing region based on the obtained resulting signals.

The display stackup may further include: a glass lens, an optically clear adhesive, and a polarizer disposed above the touch sensor layer; and one or more nitride layers between the touch sensor layer and the display layer.

The distance between the display layer and the touch sensor layer may be less than 20 μm.

### BRIEF DESCRIPTION OF DRAWINGS

FIG. 1 depicts a schematic block diagram of an exemplary input device.

FIG. 2 depicts a block diagram of an exemplary touchscreen stackup which includes a touch sensor layer and a display layer.

FIG. 3 depicts a plot of display susceptibility windows aligned with plots of touch emissions produced by a touch sensor when using square waves at 60.5 kHz and 244.5 kHz, respectively.

FIG. 4A depicts a plot of power spectral density of a highest FFT bin versus touch frequency for a square wave, and FIG. 4B depicts a plot of power spectral density of a highest FFT bin versus touch frequency for a sine wave.

FIG. 5 depicts a quadrature trapezoidal waveform that may be used to drive a touch sensor in accordance with an exemplary embodiment of the disclosure.

FIG. 6A depicts a triangular waveform that may be used to drive a touch sensor in accordance with an exemplary embodiment of the disclosure, and FIG. 6B depicts an example of a plot of power spectral density of a highest FFT bin versus touch frequency for the triangular waveform.

FIG. 7A depicts an example of a harmonic reject shape that may be used to drive a touch sensor in accordance with an exemplary embodiment of the disclosure, and FIG. 7B depicts a harmonic amplitude vs. frequency plot associated therewith. FIG. 7C depicts an exemplary circuit for generating the harmonic reject shape depicted in FIG. 7A.

FIG. 8 is a flowchart depicting an exemplary process for operating a touchscreen device in accordance with an exemplary embodiment of the disclosure.

### DETAILED DESCRIPTION

The drawings and the following detailed description are merely exemplary in nature, and are not intended to limit the disclosed technology or the application and uses of the disclosed technology. Furthermore, there is no intention to be bound by any expressed or implied theory presented in the preceding technical field, background, or the following detailed description.

In the following detailed description of exemplary embodiments, numerous details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

The following description of sensor patterns relies on terminology such as “horizontal”, “vertical”, “top”, “bottom”, and “under” to clearly describe certain geometric features of the sensor patterns. The use of these terms is not intended to introduce a limiting directionality. For example, the geometric features may be rotated to any degree, without departing from the disclosure. Further, while patterns of certain sizes are shown in the drawings, the patterns may extend and/or repeat without departing from the disclosure. For example, the use of the term columns and vertical direction is to distinguish between rows and the horizontal direction, respectively. If the input device is rectangular, any direction along the surface may be designated as the vertical direction by which a column extends and any substantially orthogonal direction along the surface may be designated as a vertical direction along which the row extends.

In many conventional touch sensors, a step-and-wait (also referred to as “stop-and-wait”) sensing scheme is used, whereby the touch sensor is driven with a square wave (the “step” comes from the sharp step of the square wave sensing waveform, and the “wait” is the time spent waiting for the resulting charge from the step to integrate before sampling, wherein the wait period starts when the rising edge of the sensing waveform stats and ends after a tuning-determined duration, based on making sure that slower RC response parts of the sensor have gotten enough time to deliver a similar amount of settling as the faster RC response parts of the sensor). However, the square waves used in step-and-wait touch sensors are not suitable for thin touchscreen devices in which the touch sensor is located very close to the display pixels (such as in a Y-OCTA touchscreen device) due to touch-to-display noise caused by the square waves, which introduces artifacts in the displayed image. Exemplary embodiments of the disclosure provide a touchscreen device having a touch sensor and a display, wherein the touch sensor is driven according to a driving scheme which reduces touch-to-display noise so as to avoid display artifacts caused by touch-to-display noise. The driving scheme in exemplary embodiments of the disclosure may be based on utilizing a quadrature trapezoid waveform, a triangle waveform, or any other waveform with a shape which produces reduced harmonic energy (e.g., a harmonic reject waveform), through which touch-to-display noise is reduced due to reducing transmitter emission harmonics which intersect with display susceptibility windows. Further, because the driving scheme in exemplary embodiments of the disclosure is compatible with existing step-and-wait touch sensor circuit designs, costly and complicated redesigning of previously developed touch sensors which use square wave step-and-wait sensing schemes can be avoided. Additionally, the benefits of step-and-wait sensing schemes are retained in exemplary embodiments of the disclosure. For example, when using a step-and-wait sensing scheme, the sensor can operate at a higher sensing frequency than when using a sine waveform, and phase compensation of the sensor response is not needed. In other words, a touch sensor using a step-and-wait sensing scheme is insensitive to differences in phase delay across the touch sensor and has a fast overall usable sensing frequency. Further, there is a lack of charger noise.

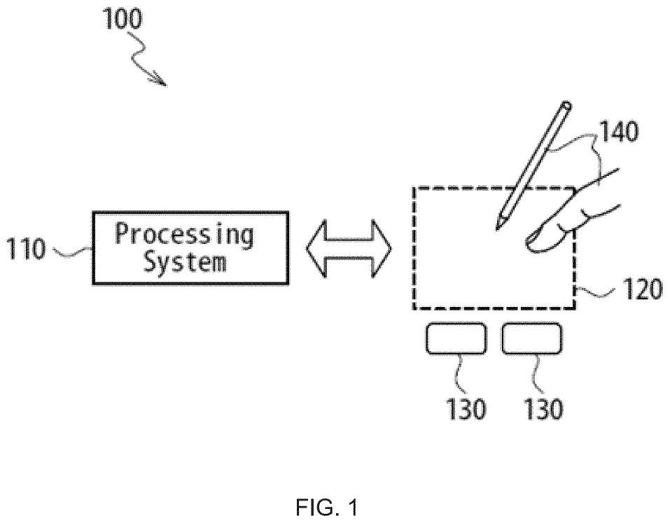

An example input device 100 is shown in FIG. 1 to provide an example environment to explain working principles of a sensor in connection with a processing system. The input device 100 may be configured to provide input to an electronic system. As used in this document, the term “electronic system” broadly refers to any system capable of electronically processing information. Some non-limiting examples of electronic systems include personal computers of all sizes and shapes, such as desktop computers, laptop computers, netbook computers, tablets, web browsers, e-book readers, and personal digital assistants (PDAs). Additional example electronic systems include composite input devices, such as physical keyboards that include input device 100 and separate joysticks or key switches. Further example electronic systems include peripherals such as data input devices, e.g., remote controllers and mice, and data output devices, e.g., display screens and printers. Other examples include remote terminals, kiosks, and video game machines, e.g., video game consoles, portable gaming devices, and the like. Other examples include communication devices, e.g., cellular phones such as smart phones, and media devices, e.g., recorders, editors, and players such as televisions, set-top boxes, music players, digital photo frames, and digital cameras. Additionally, the electronic system could be a host or a slave to the input device. The electronic system may also be referred to as electronic device.

The input device 100 can be implemented as a physical part of the electronic system, or can be physically separate from the electronic system. In one embodiment, the electronic system may be referred to as a host device. As appropriate, the input device 100 may communicate with parts of the electronic system using any one or more of the following: buses, networks, and other wired or wireless interconnections. Examples include I2C, SPI, PS/2, Universal Serial Bus (USB), Bluetooth, RF, and IRDA.

In FIG. 1, the input device 100 is shown as a capacitive sensor device configured to sense input provided by one or more input objects 140 in a sensing region 120. Example input objects 140 include fingers and styli, as shown in FIG. 1. An exemplary capacitive sensor device may be a touchpad, a touch screen, a touch sensor device and the like.

Sensing region 120 encompasses any space above, around, in and/or near the input device 100 in which the input device 100 is able to detect user input, e.g., user input provided by one or more input objects 140. The sizes, shapes, and locations of particular sensing regions may vary widely from embodiment to embodiment. In some embodiments, the sensing region 120 extends from a surface of the input device 100 in one or more directions into space until signal-to-noise ratios prevent sufficiently accurate object detection. The distance to which this sensing region 120 extends in a particular direction, in various embodiments, may be on the order of less than a millimeter, millimeters, centimeters, or more, and may vary significantly with the type of sensing technology used and the accuracy desired. Thus, some embodiments sense input that comprises: no contact with any surfaces of the input device 100; contact with an input surface, e.g., a touch surface, of the input device 100; contact with an input surface of the input device 100 coupled with some amount of applied force or pressure; and/or a combination thereof. In various embodiments, input surfaces may be provided by surfaces of casings within which the sensor electrodes reside, by face sheets applied over the sensor electrodes or any casings, etc. In some embodiments, the sensing region 120 has a rectangular shape when projected onto an input surface of the input device 100.

The input device 100 may utilize any combination of sensor components and sensing technologies to detect user input in the sensing region 120. The input device 100 comprises one or more sensing elements for detecting user input. As several non-limiting examples, the input device 100 may utilize capacitive sensing, and may further utilize elastive, resistive, inductive, magnetic, acoustic, ultrasonic, and/or optical techniques.

Some implementations are configured to provide images (e.g., of capacitive signals) that span one, two, three, or higher dimensional spaces. Some implementations are configured to provide projections of input along particular axes or planes.

In some capacitive implementations of the input device 100, voltage or current is applied to create an electric field. Nearby input objects cause changes in the electric field, and produce detectable changes in capacitive coupling that may be detected as changes in voltage, current, or the like.

Some capacitive implementations utilize arrays or other regular or irregular patterns of capacitive sensing elements to create electric fields. In some capacitive implementations, separate sensing elements may be ohmically shorted together to form larger sensor electrodes. Some capacitive implementations utilize resistive sheets, which may be uniformly resistive.

Some capacitive implementations utilize “self-capacitance” (also often referred to as “absolute capacitance”) sensing methods based on changes in the capacitive coupling between sensor electrodes and an input object (e.g., between a system ground and freespace coupling to the user). In various embodiments, an input object near the sensor electrodes alters the electric field near the sensor electrodes, thus changing the measured capacitive coupling. In one implementation, an absolute capacitance sensing method operates by modulating sensor electrodes with respect to a reference voltage, e.g., system ground, and by detecting the capacitive coupling between the sensor electrodes and input objects. In some implementations sensing elements may be formed of a substantially transparent metal mesh (e.g., a reflective or absorbing metallic film patterned to reduce or minimize visible transmission loss from the display subpixels). Further, the sensor electrodes may be disposed over a display of a display device. The sensing electrodes may be formed on a common substrate of a display device (e.g., on the encapsulation layer of a rigid or flexible organic light emitting diode (OLED) display). An additional dielectric layer with vias for a jumper layer may also be formed of a substantially transparent metal mesh material (e.g., between the user input and the cathode electrode). Alternately, the sensor may be patterned on a single layer of metal mesh over the display active area with cross-overs outside of the active area. The jumpers of the jumper layer may be coupled to the electrodes of a first group and cross over sensor electrodes of a second group. In one or more embodiments, the first and second groups may be orthogonal axes to each other. Further, in various embodiments, the absolute capacitance measurement may comprise a profile of the input object couplings accumulated along one axis and projected onto the other. In various embodiments, a modulated input object (e.g., a powered active stylus) may be received by the orthogonal electrode axes without modulation of the corresponding electrodes (e.g., relative to a system ground). In such an embodiment, both axes may be sensed simultaneously and combined to estimate stylus position.

Some capacitive implementations utilize “mutual capacitance” (also often referred to as “transcapacitance”) sensing methods based on changes in the capacitive coupling between sensor electrodes. In various embodiments, an input object near the sensor electrodes alters the electric field between the sensor electrodes, thus changing the measured capacitive coupling. In one implementation, a transcapacitive sensing method operates by detecting the capacitive coupling between one or more transmitter sensor electrodes (also referred to herein as “transmitter electrodes” or “transmitters”) and one or more receiver sensor electrodes (also referred to herein as “receiver electrodes” or “receivers”). The coupling may be reduced when an input object coupled to a system ground approaches the sensor electrodes. Transmitter sensor electrodes may be modulated relative to a reference voltage, e.g., system ground, to transmit transmitter signals. Receiver sensor electrodes may be held substantially constant relative to the reference voltage or modulated relative to the transmitter sensor electrodes to facilitate receipt of resulting signals. A resulting signal may comprise effect(s) corresponding to one or more transmitter signals, and/or to one or more sources of environmental interference, e.g., other electromagnetic signals. Sensor electrodes may be dedicated transmitters or receivers, or may be configured to both transmit and receive.

In FIG. 1, a processing system 110 is shown as part of the input device 100. The processing system 110 is configured to operate the hardware of the input device 100 to detect input in the sensing region 120. The processing system 110 comprises parts of or all of one or more integrated circuits (ICs) chips and/or other circuitry components. For example, a processing system for a mutual capacitance sensor device may comprise transmitter circuitry configured to transmit signals with transmitter sensor electrodes, and/or receiver circuitry configured to receive signals with receiver sensor electrodes. In some embodiments, the processing system 110 also comprises electronically-readable instructions, such as firmware code, software code, and/or the like. In some embodiments, components composing the processing system 110 are located together, such as near sensing element(s) of the input device 100. In other embodiments, components of processing system 110 are physically separate with one or more components close to sensing element(s) of input device 100, and one or more components elsewhere. For example, the input device 100 may be a peripheral coupled to a desktop computer, and the processing system 110 may comprise software configured to run on a central processing unit of the desktop computer and one or more ICs (in another embodiment, with associated firmware) separate from the central processing unit. As another example, the input device 100 may be physically integrated in a phone, and the processing system 110 may comprise circuits and firmware that are part of a main processor (e.g., a mobile device application processor or any other central processing unit) of the phone. In some embodiments, the processing system 110 is dedicated to implementing the input device 100. In other embodiments, the processing system 110 also performs other user input functions, such as operating display screens, measuring input forces, measuring tactile switch state, driving haptic actuators, etc.

The processing system 110 may be implemented as a set of modules that handle different functions of the processing system 110. Each module may comprise circuitry that is a part of the processing system 110, firmware, software, or a combination thereof. In various embodiments, different combinations of modules may be used. Example modules include hardware operation modules for operating hardware such as sensor electrodes and display screens, data processing modules for processing data such as sensor signals and positional information, and reporting modules for reporting information. Further example modules include sensor operation modules configured to operate sensing element(s) to detect input, identification modules configured to identify gestures such as mode changing gestures, and mode changing modules for changing operation modes.

In some embodiments, the processing system 110 responds to user input (or lack of user input) in the sensing region 120 directly by causing one or more actions. Example actions include changing operation modes, as well as GUI actions such as cursor movement, selection, menu navigation, and other functions. In some embodiments, the processing system 110 provides information about the input (or lack of input) to some part of the electronic system, e.g., to a central processing system of the electronic system that is separate from the processing system 110, if such a separate central processing system exists. In some embodiments, some part of the electronic system processes information received from the processing system 110 to act on user input, such as to facilitate a full range of actions, including mode changing actions and GUI actions.

For example, in some embodiments, the processing system 110 operates the sensing element(s) of the input device 100 to produce electrical signals indicative of input (or lack of input) in the sensing region 120. The processing system 110 may perform any appropriate amount of processing on the electrical signals in producing the information provided to the electronic system. For example, the processing system 110 may digitize analog electrical signals obtained from the sensor electrodes. As another example, the processing system 110 may perform filtering or other signal conditioning. The filtering may comprise one or more of demodulating, sampling, weighting, and accumulating of analog or digitally converted signals (e.g., for FIR digital or IIR switched capacitor filtering) at appropriate sensing times. The sensing times may be relative to the display output periods (e.g., display line update periods or blanking periods). As yet another example, the processing system 110 may subtract or otherwise account for a baseline, such that the information reflects a difference between the electrical signals from user input and the baseline signals. A baseline may account for display update signals (e.g., subpixel data signal, gate select and deselect signal, or emission control signal) which are spatially filtered (e.g., demodulated and accumulated) and removed from the lower spatial frequency sensing baseline. Further, a baseline may compensate for a capacitive coupling between the sensor electrodes and one or more nearby electrodes. The nearby electrodes may be display electrodes, unused sensor electrodes, and or any proximate conductive object. Additionally, the baseline may be compensated for using digital or analog means. As yet further examples, the processing system 110 may determine positional information, recognize inputs as commands, recognize handwriting, and the like.

“Positional information” as used herein broadly encompasses absolute position, relative position, velocity, acceleration, and other types of spatial information. Exemplary “zero-dimensional” positional information includes near/far or contact/no contact information. Exemplary “one-dimensional” positional information includes positions along an axis. Exemplary “two-dimensional” positional information includes motions in a plane. Exemplary “three-dimensional” positional information includes instantaneous or average velocities in space. Further examples include other representations of spatial information. Historical data regarding one or more types of positional information may also be determined and/or stored, including, for example, historical data that tracks position, motion, or instantaneous velocity over time.

In some embodiments, the input device 100 is implemented with additional input components that are operated by the processing system 110 or by some other processing system. These additional input components may provide redundant functionality for input in the sensing region 120, or some other functionality. FIG. 1 shows buttons 130 near the sensing region 120 that can be used to facilitate selection of items using the input device 100. Other types of additional input components include sliders, balls, wheels, switches, and the like. Conversely, in some embodiments, the input device 100 may be implemented with no other input components.

In some embodiments, the input device 100 comprises a touchscreen interface, and the sensing region 120 overlaps at least part of a display screen. For example, the sensing region 120 may overlap at least a portion of an active area of a display screen (or display panel). The active area of the display panel may correspond to a portion of the display panel where images are updated. In one or more embodiments, the input device 100 may comprise substantially transparent sensor electrodes (e.g., ITO, metal mesh, etc.) overlaying the display screen and provide a touchscreen interface for the associated electronic system. The display panel may be any type of dynamic display capable of displaying a visual interface to a user, and may include any type of light emitting diode (LED), OLED, cathode ray tube (CRT), liquid crystal display (LCD), plasma, electroluminescence (EL), or other display technology. The input device 100 and the display panel may share physical elements. For example, some embodiments may utilize some of the same electrical components for displaying and sensing. As another example, the display panel may be operated in part or in total by the processing system 110.

A cathode electrode of an OLED display may provide a low impedance screen between one or more display electrodes and the sensor electrodes which may be separated by a thin encapsulation layer. For example, the encapsulation layer may be about 10 μm. Alternatively, the encapsulation layer may be less than 10 μm or greater than 10 μm. Further, the encapsulation layer may be comprised of a pin hole free stack of conformal organic and inorganic dielectric layers.

It should be understood that while many embodiments of the disclosure are described in the context of a fully functioning apparatus, the mechanisms of the disclosure are capable of being distributed as a program product, e.g., software, in a variety of forms. For example, the mechanisms of the disclosure may be implemented and distributed as a software program on information bearing media that are readable by electronic processors, e.g., non-transitory computer-readable and/or recordable/writable information bearing media readable by the processing system 110. Additionally, the embodiments of the disclosure apply equally regardless of the particular type of medium used to carry out the distribution. Examples of non-transitory, electronically readable media include various discs, memory sticks, memory cards, memory modules, and the like. Electronically readable media may be based on flash, optical, magnetic, holographic, or any other storage technology.

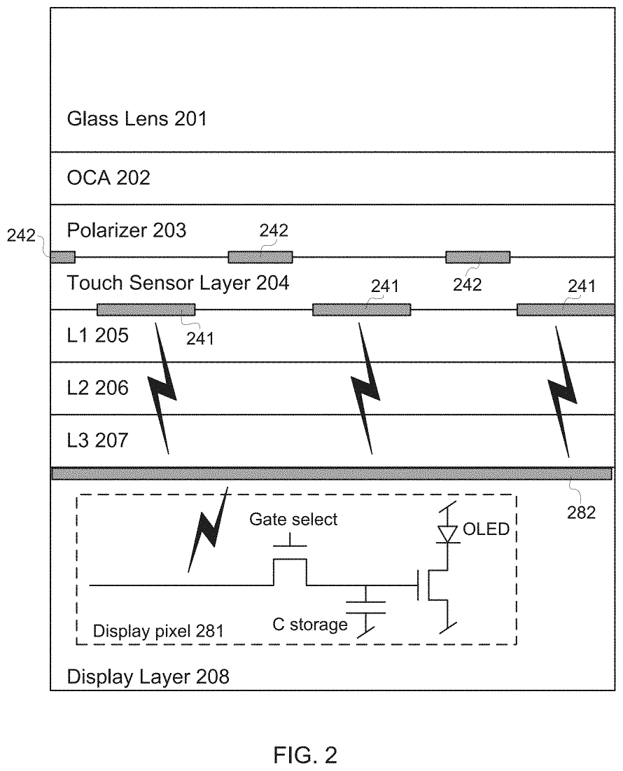

FIG. 2 depicts a cross-section of an exemplary touchscreen stackup which includes a touch sensor layer 204 (which may also be referred to as a “touch sensor”) and a display layer 208 (which may also be referred to a “display device”). In the depicted example, the stackup is a Y-OCTA stackup which includes glass lens 201, optically clear adhesive (OCA) 202, a polarizer 203, the touch sensor layer 204, an L1 layer 205, an L2 layer 206, an L3 layer 207, and the display layer 208. The L1, L2 and L3 layers 205, 206 and 207 may be multiple layers of nitride used to encapsulate OLEDs of the display layer 208 to prevent oxygen from getting in. The touch sensor layer 204 is configured to perform touch sensing operations (e.g., including generating a driving waveform, obtaining resulting signals based on the driving waveform, and determining presence and/or movement of an input object based on the resulting signals), and in this example, the touch sensor layer 204 includes transmitter electrodes 241 on a bottom side of the touch sensor layer 204 and receiver electrodes 242 on a top side of the touch sensor layer 204. The transmitter electrodes 241 and receiver electrodes 242 are shown oriented in the same direction, but in other embodiments, transmitter electrodes 241 and receiver electrodes 242 may be oriented perpendicularly relative to one another or in other arrangements. The display layer 208 includes a cathode 282 and a plurality of display pixels 281, wherein a circuit diagram of a respective display pixel 281 is included for reference (depicting a gate select, storage capacitor, and OLED of the display pixel). The display layer 208 is configured to output image data during a display operation of the touchscreen device.

In an exemplary embodiment, the glass lens 201 has a thickness of 400 μm and a dielectric constant of 7, the OCA 202 has a thickness of 100 μm and a dielectric constant of 3.0, the polarizer 203 has a thickness of 100 μm and a dielectric constant of 4.0, the touch sensor layer 204 has a thickness of 0.3 μm and a dielectric constant of 7, the L1 layer 205 has a thickness of 0.7 μm and a dielectric constant of 7, the L2 layer 206 has a thickness of 8 μm and a dielectric constant of 2.5, and the L3 layer 207 has a thickness of 1 μm and a dielectric constant of 6.0.

As shown in FIG. 2, operation of the transmitter electrodes 241 for touch sensing using the touch sensor of the touch sensor layer 204 result in “touch emissions” (i.e., emissions from the touch sensor during touch sensing) from the transmitter electrodes 241, which are received by the cathode 282 of the display layer 208. This in turn causes the cathode 282 to produce interference on respective display pixels 281 of the display layer 208. As discussed above, when the distance between the touch sensor layer 204 and the display layer 208 is relatively small and the voltage swing of the touch sensing waveform is sufficiently high, the interference on the display pixels 281 may be high enough to produce artifacts in the output provided by the display of the display layer 208.

In the stackup of FIG. 2, the distance between the touch sensor layer 204 and the cathode 282 may be around 8 μm, and a typical operating voltage may be around 2 V. Generally speaking, with a typical operating voltage of around 2 V, touch-to-display noise may become an issue in stackups where the distance between the touch sensor layer and the cathode 282 is under 20-30 μm, and it will be appreciated that the magnitude of the touch-to-display noise issue is a gradient in terms of the distance (i.e., the smaller the distance, the greater the issue).

It will be appreciated that although the example shown in FIG. 2 includes a transcapacitive touch sensor layer 204 having both transmitter electrodes 241 and receiver electrodes 242, the principles discussed herein are not limited thereto. Rather, the principles of the disclosure are applicable to any type of capacitive sensor with any type of electrode arrangement in which there may be touch emissions affecting a cathode of a display proximate to the capacitive sensor. Due to the size and location of the cathode of a display in a display and touch sensor stackup, the interference resulting from touch emissions is agnostic as to the way in which those touch emissions are produced. What matters with respect to touch-to-display noise is whether the touch emissions are substantial enough from an overall perspective so as to cause artifacts in the display output. Thus, it will be appreciated that the depicted configuration of transmitter electrodes 241 and receiver electrodes 242 in FIG. 2 may be replaced with various other configurations of electrodes, including, for example, a single layer of absolute capacitance electrodes.

To understand why the display pixels 281 of the display layer 208 are susceptible to touch-to-display noise, the display pixels can be thought of as unintentional samplers which sample signals, without anti-aliasing, in a manner similar to an analog front end (AFE). In particular, the storage capacitor of a respective display pixel implicitly performs sampling at the HLine rate, and also aliases down signals that are above its sampling rate. In view of the foregoing, if a touch sensor using a step-and-wait square wave waveform results in touch emissions at an HLine harmonic, touch-to-display noise may be introduced into the display, and such touch-to-display noise cannot be prevented by lowering voltage or lowering slew rate.

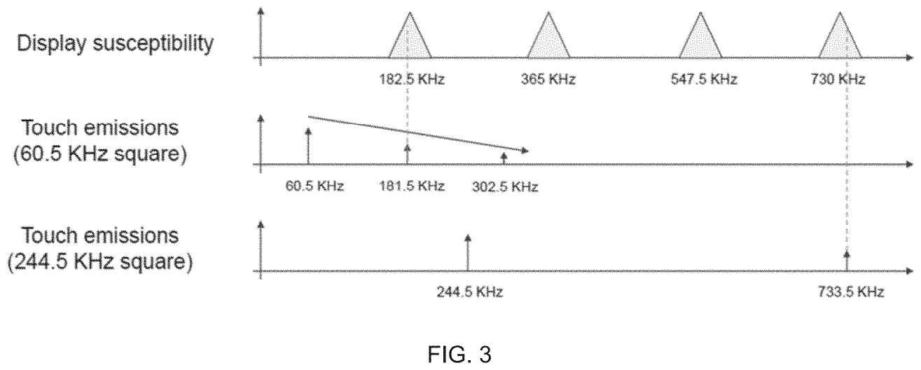

FIG. 3 depicts a plot of display susceptibility windows aligned with plots of touch emissions produced by a touch sensor when using square waves at 60.5 kHz and 244.5 kHz, respectively. In this example, the display susceptibility windows are disposed at around 182.5 kHz, 365 kHz, 547.5 kHz and 730 kHz because the display's HLine rate is 182.5 kHz. This is shown in the top plot of FIG. 3, wherein each triangle represents a respective display susceptibility window centered around a respective frequency, such that the display is susceptible to touch-to-display noise caused by touch emissions falling within the display susceptibility window. The display's gate select signal samples at the HLine rate such that any noise at multiples of the HLine frequency will be sampled by the display and generate noise in the image. In other words, when the display is updating a line, that line is vulnerable to being corrupted by outside voltages coupling into the source line. The middle plot shows the touch emissions for a 60.5 kHz square wave being used to drive the touch sensor, and since a square wave has odd harmonics going down as 1/N, there are harmonic touch emissions at 181.5 kHz falling within the first display susceptibility window. The bottom plot shows the touch emissions for a 244.5 kHz square wave being used to drive the touch sensor, which has harmonic touch emissions at 733.5 kHz falling within the fourth display susceptibility window. Thus, as can be seen in FIG. 3, even though the square waves in the middle and bottom plots have nominal sensing frequencies which are far away from the HLine rate of 182.5 kHz, these square waves can still cause touch-to-display noise due to harmonics, and if the magnitude of the emissions is high enough, artifacts may appear in the display output.

It will be appreciated that different devices may have different HLine rates, as the HLine rate is a function of the display resolution and the display refresh rate. Thus, the specific display susceptibility windows of a respective device are based on the respective display resolution and the respective display refresh rate of the respective device. There is a rough formula of HLine rate=display_refresh_rate*(vertical_resolution+number_of_HLines_in_VBlank), but the susceptibility windows of respective displays may vary based on the exact pixel circuit structure for a respective display and how it is being sequenced.

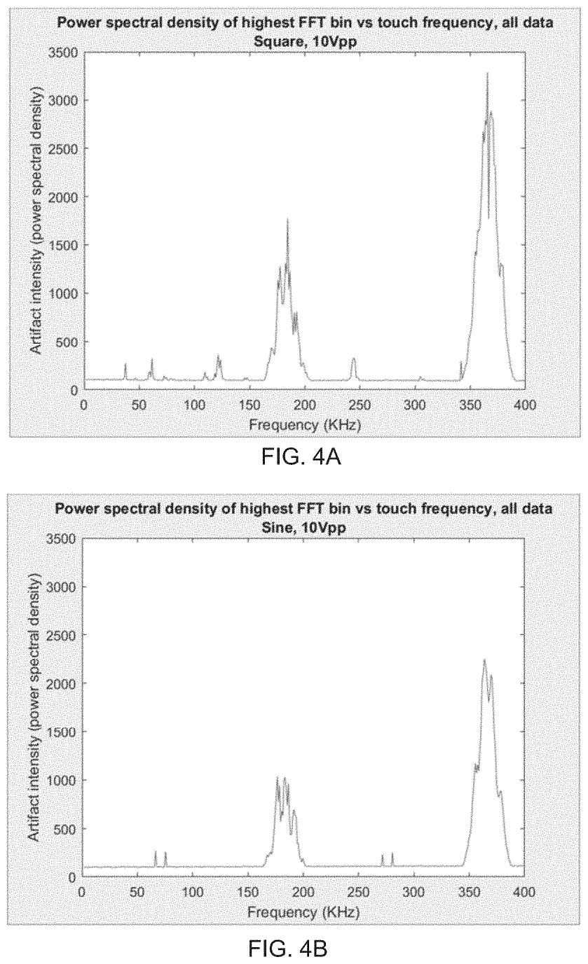

FIG. 4A depicts a plot of power spectral density of a highest FFT bin versus touch frequency for a square wave (which has 1/N harmonics), and FIG. 4B depicts a plot of power spectral density of a highest FFT bin versus touch frequency for a sine wave (which does not have any harmonics). In both plots, the vertical axis shows the intensity corresponding to a potential artifact that may appear if a respective touch frequency were to fall within a display susceptibility window. As can be seen in these plots, both have a set of peaks at around 160-200 kHz and another set of peaks around 340-390 kHz, but for the square wave, there are also several noticeable peaks (e.g., around 245 kHz, 120 kHz, 55 kHz, etc.), whereas for the sine wave, the floor is very flat because sine waves do not produce harmonics. The messy floor of the square wave makes it difficult to mitigate or prevent touch-to-display while using a square wave to drive a touch sensor, as at least some of the harmonics projecting out from the floor are likely to intersect with display susceptibility windows.

From FIGS. 4A-4B, it may appear preferable to use a sine wave instead of a square wave for driving a touch sensor to reduce touch-to-display noise, but there are reasons why a sine wave is not suitable for driving a touch sensor. For example, a sine wave driver is more difficult to implement and takes up more silicon area than conventional square wave drivers, and using a sine wave driver introduces a sensitivity to differences in phase delay across the touch sensor and results in a slower overall usable sensing frequency.

In an exemplary embodiment, the disclosure provide a processing system for a touch sensor in a touchscreen device which is configured to drive the touch sensor using a quadrature trapezoidal waveform. The use of a quadrature trapezoidal waveform achieves the benefits associated with using a sine waveform with respect to reduction of touch-to-display noise while avoiding the drawbacks of using a sine waveform, as the quadrature trapezoidal waveform has odd harmonics going down as 1/N\hat{ }2 and can be generated using square wave driving circuitry. Driving a step-and-wait touch sensor using a quadrature trapezoidal waveform can thus be achieved without complicated modifications to existing sensor circuitry, and the use of the quadrature trapezoidal waveform provides a great balance of fast rise time and good spectral properties.

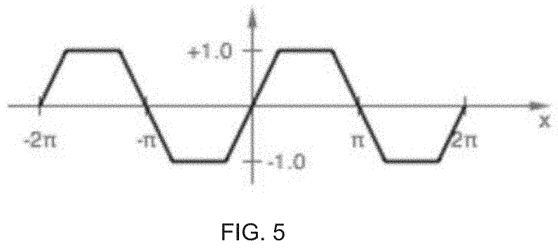

FIG. 5 depicts a quadrature trapezoidal waveform that may be used to drive a touch sensor in accordance with an exemplary embodiment of the disclosure. As can be seen in FIG. 5, for a respective period of 2π a in the quadrature trapezoidal waveform shape, ¼ of the period corresponds to a linear rise in amplitude, ¼ of the period is spent flat at the maximum amplitude (normalized within the depiction of FIG. 5A as “+1.0”), ¼ of the period corresponds to a linear decrease in amplitude, and ¼ of the period is spent flat at the minimum amplitude (normalized within the depiction of FIG. 5A as “−1.0”).

The quadrature trapezoidal waveform of FIG. 5 may be used with a step-and-wait sensing scheme because the step-and-wait sensing scheme is mainly concerned with how big the step is and how long the wait is, and is flexible and robust with regard to how the step is implemented. Thus, the fact that the step takes a bit longer with respect to a quadrature trapezoidal waveform relative to a square waveform does not negatively affect the performance of a step-and-wait touch sensor.

It will be appreciated that the non-normalized driving voltage amplitude may vary in different embodiments. For example, in one exemplary embodiment, a driving voltage of 9 V is used for one sensing mode (e.g., a transcapacitive sensing mode) and a second driving voltage of 2 V is used for another sensing mode (e.g., an absolute capacitance sensing mode), and the principles discussed herein with respect to reducing driving voltage harmonics in display susceptibility windows are applicable for both modes. It will be appreciated that the driving voltages for the two modes may be different due to different background load capacitances and the AFE having a fixed charge handling capability.

Because the quadrature trapezoidal waveform has odd harmonics going down as 1/N\hat{ }2, the floor of a power spectral density plot for the quadrature trapezoidal waveform would be substantially flat, similar to the power spectral density plot of FIG. 4B for a sine waveform and unlike the power spectral density plot of FIG. 4A for a square waveform. Thus, the use of the quadrature trapezoidal waveform reduces generation of harmonic touch transmissions which interfere with a display proximate to the touch sensor, thereby reducing touch-to-display noise and avoiding display artifacts caused by touch-to-display.

In another exemplary embodiment, the disclosure provides a processing system for a touch sensor in a touchscreen device which is configured to drive the touch sensor using a triangular waveform. Similar to the use of a quadrature trapezoidal waveform, the use of a triangular waveform also achieves the benefits associated with using a sine waveform with respect to reduction of touch-to-display noise while avoiding the drawbacks of using a sine waveform, as the triangular waveform also has odd harmonics going down as 1/N\hat{ }2 and can be generated using square wave driving circuitry. Driving a step-and-wait touch sensor using a triangular waveform can thus be achieved without complicated modifications to existing sensor circuitry, and the use of the triangular waveform also provides a good balance of fast rise time and good spectral properties.

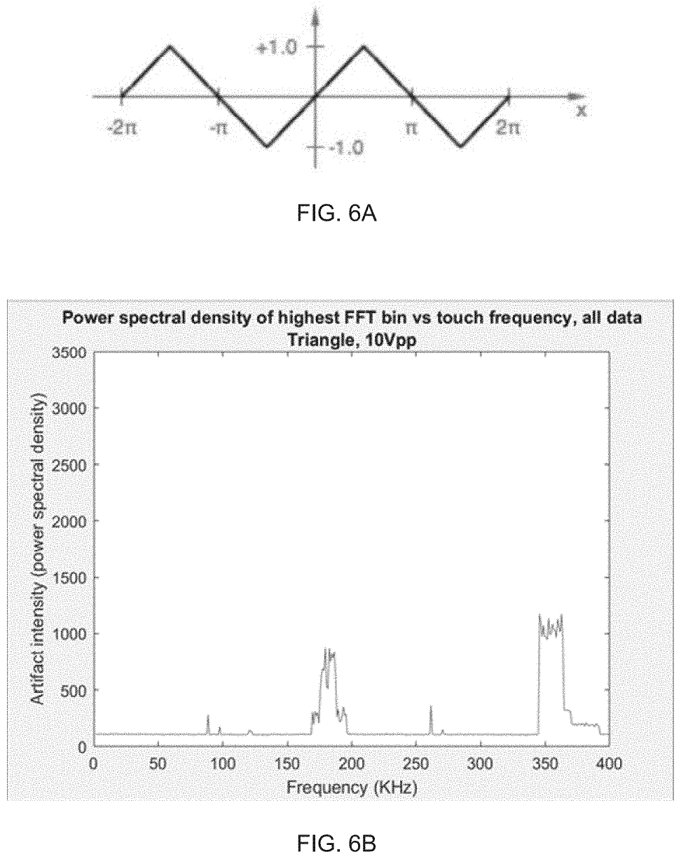

FIG. 6A depicts a triangular waveform that may be used to drive a touch sensor in accordance with an exemplary embodiment of the disclosure, and FIG. 6B depicts an example of a plot of power spectral density of a highest FFT bin versus touch frequency for the triangular waveform. As can be seen in FIG. 6A, for a respective period of a in the triangular waveform shape, ½ of the period corresponds to a linear rise in amplitude, and ½ of the period corresponds to a linear decrease in amplitude, whereby the amplitude increases from a normalized value of −1.0 to +1.0 and then decreases back from +1.0 to −1.0.

As mentioned above, the step-and-wait sensing scheme is mainly concerned with how big the step is and how long the wait is, and is flexible and robust with regard to how the step is implemented. Thus, the triangular waveform of FIG. 6A, for which a step also takes a bit longer relative to a square waveform, may also be used for a step-and-wait touch sensor.

Further, as discussed above, it will be appreciated that the non-normalized driving voltage amplitude may vary in different embodiments. For example, in one exemplary embodiment, a driving voltage of 9 V is used for one sensing mode and a second driving voltage of 2 V is used for another sensing mode, and the principles discussed herein with respect to reducing driving voltage harmonics in display susceptibility windows are applicable for both modes.

Additionally, as can be seen from FIG. 6B, because the triangular waveform has odd harmonics going down as 1/N\hat{ }2, the floor of the power spectral density plot is substantially flat, similar to the power spectral density plot of FIG. 4B for a sine waveform and unlike the power spectral density plot of FIG. 4A for a square waveform. Thus, the use of the triangular waveform reduces generation of harmonic touch transmissions which interfere with a display proximate to the touch sensor, thereby reducing touch-to-display noise and avoiding display artifacts caused by touch-to-display.

In another exemplary embodiment, the disclosure provide a processing system for a touch sensor in a touchscreen device which is configured to drive the touch sensor using a waveform having a harmonic reject shape. Different types of harmonic reject shapes may be used, so long as the harmonic reject shape is configured to sufficiently reduce interference of harmonics with display susceptibility windows to avoid noticeable artifacts caused by touch-to-display noise in the display output.

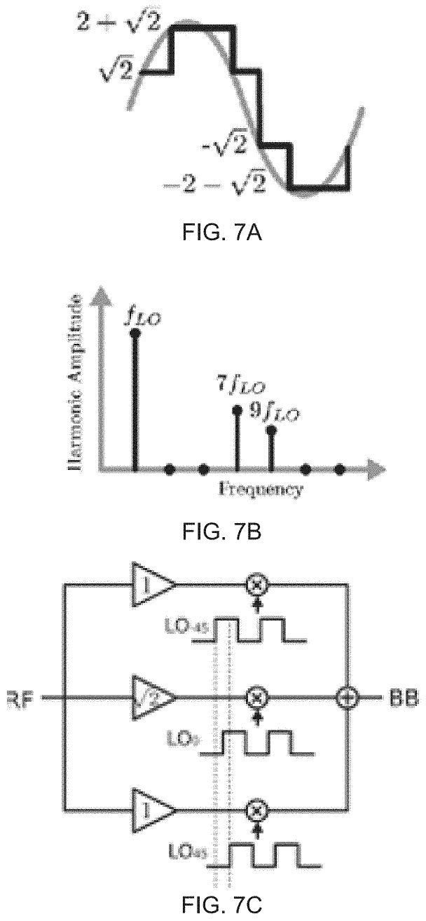

FIG. 7A depicts an example of a harmonic reject shape that may be used to drive a touch sensor in accordance with an exemplary embodiment of the disclosure, and FIG. 7B depicts a harmonic amplitude vs. frequency plot associated therewith. As can be seen in the plot of FIG. 7B, the waveform loses the 3^{rd} and 5^{th} harmonics relative to a square wave, and is thus able to reduce interference of such harmonics with display susceptibility windows. It will be appreciated that square waves with 50% duty cycle only have odd harmonics, so there are no even harmonics to remove, and removal of the 3^{rd} and 5^{th} harmonics has greater value that removing higher order harmonics (e.g., 7^{th} harmonic and beyond) because lower order harmonics have relatively more energy.

FIG. 7C depicts an exemplary circuit for generating the harmonic reject shape depicted in FIG. 7A. The circuit is a harmonic rejection mixer (HRM) which includes three square wave generators which generate three respective square waves at respective amplitudes (1, \sqrt{2}, 1) and respective phases (−45°, 0°,45°), and combines the three square waves to generate the harmonic reject shape Thus, as can be seen from FIG. 7C, the hardware used for generating the harmonic reject shape to remove the 3^{rd} and 5^{th} harmonics is simple and inexpensive.

It will be appreciated that in various exemplary embodiments, the amount of harmonic content that is to be removed may be customized based on the display susceptibility windows corresponding to the HLine frequency and the HLine harmonics. The harmonics of the driving waveform which are removed may be those which would alias into the display susceptibility windows, such that the frequency space used by the driving waveform of the touch sensor reduces interference with the display susceptibility windows.

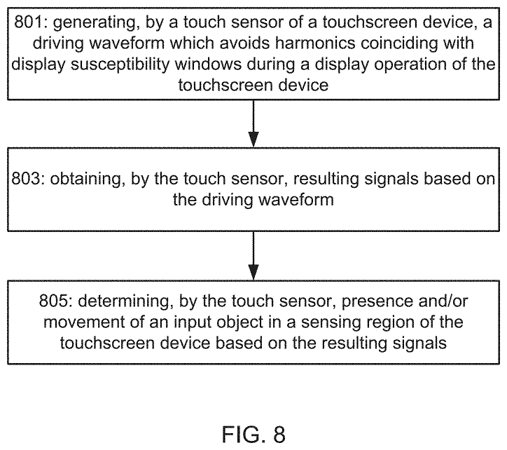

FIG. 8 is a flowchart depicting an exemplary process for operating a touchscreen device in accordance with an exemplary embodiment of the disclosure. At stage 801, a touch sensor of a touchscreen device (including both the touch sensor and a display device proximate to the touch sensor) generates a driving waveform for touch sensing, wherein the driving waveform is configured to reduce harmonics which coincide with display susceptibility windows of the display device during a display operation of the touchscreen device using the display device (thereby avoiding noticeable artifacts caused by touch-to-display noise in the display output). For example, the driving waveform may be a quadrature trapezoidal waveform, a triangular waveform, or a harmonic reject waveform, as discussed above in connection with FIGS. 5, 6A and 7A.

At stage 803, the touch sensor obtains resulting signals based on the driving waveform. For example, the touch sensor may be a step-and-wait touch sensor, and obtaining the resulting signals may include performing integration while a resulting charge from the drive voltage flows in from the sensor, followed by sampling once the integration period is over.

At stage 805, a processing system of the touch sensor determines presence and/or movement of an input object in a sensing region of the touchscreen device based on the obtained resulting signals. For example, the touchscreen device may determine that a finger is now present in the sensing region, or that the finger has moved in a certain direction, or that a gesture (such as a tap or double-tap) has been performed by the finger.

It will be appreciated that although the above-discussed embodiments have discussed step-and-wait touchscreen devices in which touch-to-display noise is an issue, it will be appreciated that embodiments of the disclosure are not limited thereto. For example, to the extent touch-to-display noise (or “driver-to-display” noise caused by a driving waveform) is an issue for other types of sensors proximate to display devices, such as fingerprint sensors, stylus sensors, or elastive, resistive, inductive, magnetic, acoustic, ultrasonic, and/or optical sensors, the principles discussed herein may be applied to reduce such touch-to-display noise or driver-to-display noise in such other types of devices.

It will further be appreciated that, as discussed above, display devices in touchscreen display devices have display susceptibility windows based on a resolution and a refresh rate of the display device, and embodiments of the driving waveform discussed herein are configured to reduce (which may include completely eliminating) harmonics which coincide with frequency ranges of the display susceptibility windows, thereby reducing (which may include completely eliminating) touch-to-display noise and avoiding visible display artifacts caused by touch-to-display noise relative to using a square wave as the driving waveform for a step-and-wait sensing scheme.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Exemplary embodiments are described herein. Variations of those exemplary embodiments may become apparent to those of ordinary skill in the art upon reading the foregoing description. It is understood that skilled artisans are able to employ such variations as appropriate, and the invention may be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A touchscreen display device, comprising:
a display device configured to output image data during a display operation of the touchscreen display device; and
a touch sensor configured to perform touch sensing using a step-and-wait sensing scheme, wherein performing touch sensing includes:
generating a driving waveform for touch sensing during the display operation of the touchscreen display device, wherein the driving waveform is a quadrature trapezoidal waveform, a triangular waveform, or a harmonic reject waveform, and wherein the driving waveform is configured to reduce touch-to-display interference with respect to the display operation;
obtaining resulting signals based on the generated driving waveform; and
determining presence and/or movement of an input object in a sensing region of the touchscreen display device based on the obtained resulting signals.

2. The touchscreen display device according to claim 1, wherein the display device and the touch sensor are disposed in respective layers of a stackup, and wherein the distance between the display device and the touch sensor is less than 20 μm.

3. The touchscreen display device according to claim 1, wherein the driving waveform is the quadrature trapezoidal waveform.

4. The touchscreen display device according to claim 1, wherein the driving waveform is the triangular waveform.

5. The touchscreen display device according to claim 1, wherein the driving waveform is the harmonic reject waveform.

6. The touchscreen display device according to claim 5, wherein the touch sensor comprises a harmonic rejection mixer configured to generate the harmonic reject waveform, and wherein the harmonic rejection mixer comprises a plurality of square wave generators, each configured to generate a square wave having a respective amplitude and phase offset.

7. The touchscreen display device according to claim 5, wherein the driving voltage harmonics of the harmonic reject waveform do not include third and fifth harmonics of a square wave.

8. A method for step-and-wait sensing, comprising:
generating, by a touch sensor of a touchscreen display device, a driving waveform for touch sensing during a display operation of a display device of the touchscreen display device, wherein the driving waveform is a quadrature trapezoidal waveform, a triangular waveform, or a harmonic reject waveform, and wherein the driving waveform is configured to reduce touch-to-display interference with respect to the display operation;
obtaining, by the touch sensor, resulting signals based on the generated driving waveform; and
determining, by the touch sensor, presence and/or movement of an input object in a sensing region of the touchscreen display device based on the obtained resulting signals.

9. The method according to claim 8, wherein the display device and the touch sensor are disposed in respective layers of a stackup, and wherein the distance between the display device and the touch sensor is less than 20 μm.

10. The method according to claim 8, wherein the driving waveform is the quadrature trapezoidal waveform.

11. The method according to claim 8, wherein the driving waveform is the triangular waveform.

12. The method according to claim 8, wherein the driving waveform is the harmonic reject waveform.

13. The method according to claim 12, wherein the touch sensor comprises a harmonic rejection mixer configured to generate the harmonic reject waveform, and wherein the harmonic rejection mixer comprises a plurality of square wave generators, each configured to generate a square wave having a respective amplitude and phase offset.

14. The method according to claim 12, wherein the driving voltage harmonics of the harmonic reject waveform do not include third and fifth harmonics of a square wave.

15. A display stackup, comprising:
a display layer comprising a plurality of display pixels configured to output image data during a display operation; and
a touch sensor layer, wherein a touch sensor of the touch sensor layer is configured to perform touch sensing using a step-and-wait sensing scheme, wherein performing touch sensing includes:
generating a driving waveform for touch sensing during the display operation, wherein the driving waveform is a quadrature trapezoidal waveform, a triangular waveform, or a harmonic reject waveform, and wherein the driving waveform is configured to reduce touch-to-display interference with respect to the display operation;
obtaining resulting signals based on the generated driving waveform; and
determining presence and/or movement of an input object in a sensing region based on the obtained resulting signals.

16. The display stackup according to claim 15, wherein the display stackup further comprises:
a glass lens, an optically clear adhesive, and a polarizer disposed above the touch sensor layer; and
one or more nitride layers between the touch sensor layer and the display layer.

17. The display stackup according to claim 15, wherein the distance between the display layer and the touch sensor layer is less than 20 μm.

18. The display stackup according to claim 15, wherein the driving waveform is the quadrature trapezoidal waveform.

19. The display stackup according to claim 15, wherein the driving waveform is the triangular waveform.

20. The display stackup according to claim 15, wherein the driving waveform is the harmonic reject waveform.

21. The touchscreen display device according to claim 1, wherein driving voltage harmonics of the driving waveform are located outside of display susceptibility windows of the display device.
